(19) United States
(12) Patent Application Publication
(10) Pub. No.: US 2010/0001409 A1
(43) Pub. Date: Jan. 7, 2010

(54) SEMICONDUCTOR DEVICE AND METHOD OF MANUFACTURING THEREOF

(75) Inventors: Aurelie Humbert, Bruxelles (BE); Romano Hoofman, Geel (BE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP, B.V., Eindhoven (NL)

(21) Appl. No.: 12/514,214

(22) PCT Filed: Oct. 29, 2007
(86) PCT No.: PCT/IB2007/054385

§ 371 Date: May 8, 2009

(30) Foreign Application Priority Data
Nov. 9, 2006 (EP) 06123746.7

(51) Int. Cl. H01L 23/48; H01L 21/768; H01L 23/522

(52) U.S. Cl. 257/774; 438/637; 257/E21.585; 257/E23.011; 257/E23.142; 257/E23.155

(57) ABSTRACT

The invention relates to a semiconductor device comprising: a substrate (1), the substrate (1) comprising a body (5), the body (5) having a surface, the substrate (1) being provided with an insulating layer (10) on the surface of the body (1);—a conductor (25) with insulating sidewall spacers (22) located in the insulating layer (10), the conductor (25) having a current-flow direction during operation, the conductor (25) having a first width, the insulating sidewall spacers (22) each having a second width being smaller than the first width of the conductor (25), the first width and the second width being measured in a direction perpendicular to the current-flow direction of the conductor (25) and parallel to said surface, the conductor (25) having a first top surface extending parallel to said surface, the insulating sidewall spacers (22) having a second top surface, and airgaps (30) located in the insulating layer (10) adjacent to the insulating sidewall spacers (22), characterized in that the first top surface coincides with the second top surface, and in that the airgaps (30) extend from the surface of the body (5) to said first and second top surface. The invention further relates to a method of manufacturing such a semiconductor device. The semiconductor device according to the invention enables a lower resistance of the conductor while still providing a tolerance for unlanded vias.

### FIELD OF THE INVENTION

The invention relates to semiconductor device comprising:
a substrate, the substrate comprising a body, the body having a surface, the substrate being provided with an insulating layer on the surface of the body;
a conductor with insulating sidewall spacers located in the insulating layer, the conductor having a current-flow direction during operation, the conductor having a first width, the insulating sidewall spacers each having a second width being smaller than the first width of the conductor, the first width and the second width being measured in a direction perpendicular to the current-flow direction of the conductor and parallel to said surface, the conductor having a first top surface extending parallel to said surface, the insulating sidewall spacers having a second top surface, and
airgaps located in the insulating layer adjacent to the insulating sidewall spacers.

The invention further relates to a method of manufacturing such a semiconductor device.

### BACKGROUND OF THE INVENTION

A semiconductor device is known US2001/0016412 A1. This document discloses an interconnect structure having a substrate having devices already formed thereon. A dielectric layer covers over the substrate. A conductive structure having at least two substructures separated by an air gap is formed on the dielectric layer. A capping layer covers the conductive structure and the air gap. An additional cap layer is formed on the conductive structures. A side dielectric layer, such as a spacer, is formed on sidewalls of the conductive structures and the cap layer. The airgap is formed through a sacrificial layer that is consumed away later. The airgap is enclosed by the side dielectric layer from the side. This side dielectric layer can prevent the additional cap layer from being etched through, resulting in exposing the air gap. The additional cap layer is chosen to include a material, which has a higher etching ratio to the capping layer and also to the side dielectric layer. The capping layer at a portion above the air gap also fills into the air gap by a predetermined distance. An etching stop layer is formed on the capping layer. An inter-metal dielectric layer is formed on the etching stop layer. The inter-metal dielectric layer, the etching stop layer and the capping layer are patterned to form an opening that exposes a top surface of the conductive structure. The opening also exposes a top portion of a sidewall of the side dielectric layer if a misalignment occurs, but the opening does not expose the air gap due to protection from the predetermined distance of the capping layer within the air gap and the side dielectric layer. A next level of conductive structure can be formed to fill the opening. A liner layer can be also formed on a sidewall of the substructure interfacing the air gap, so as to protect the conductive structure.

A drawback of the known semiconductor device is that at a specific width of the conductor the cross-sectional area available for the conductor is significantly reduced by the required additional capping layer, which results in an increased resistance of the conductive structure.

### SUMMARY OF THE INVENTION

It is an object of the invention to provide a semiconductor device that enables a lower resistance of the conductor while still providing a tolerance for unlanded vias.

The invention is defined by the independent claims. The dependent claims define advantageous embodiments.

The object of the invention is realized in that a semiconductor device in accordance with the opening paragraph is provided, which is characterized in that the first top surface coincides with the second top surface, and in that the airgaps extend from the surface of the body to said first and second top surface. The invention is based upon the insight that the problem resulting from a misalignment in a via which has to land on the conductor (unlanded via) can be solved with the spacers themselves. This can be done by making the spacers extend to the top of the conductor while at the same time making the airgaps extend to the top surface of the spacer and the conductor. This combination of features excludes the possibility of a capping layer that extends to below the top surface of the conductor. Above that, such capping layer is not needed anymore. The combination of all mentioned features further makes the conductor benefit fully from the vertical space available in the insulating layer, which on its turn allows for a larger cross-sectional area of the conductor at a specific interconnect width. A larger cross-sectional area implies a lower interconnect resistance and thus the object of the invention is achieved.

The semiconductor device according to the invention also provides, as an additional advantage over the known semiconductor device, a less complex device, because there are no capping layers at all needed for tolerating the unlanded vias.

In an advantageous embodiment of the semiconductor device according to the invention the substrate further comprises a further insulating layer being provided on top of the insulating layer, the further insulating layer being provided with a further opening, the further opening being filled with a further conductor, wherein at least one part of the further conductor lands on the first top surface of the conductor. This embodiment is advantageous because an unlanded via does not necessarily end up in one of the airgaps next to the spacers. Such a situation would be detrimental for the reliability of the semiconductor device. The insulating sidewall spacers each have a second width, which is smaller than the first width of the conductor. This misalignment tolerance of a via is about equal to the second width of the insulating spacers. When a non-conductive liner is used around the conductor as a diffusion barrier the width of this liner must be subtracted from the width of the insulating spacers in order to get the maximum misalignment tolerance.

Preferably, the width of the insulating sidewall spacers lies between 5% and 40% of the width of the conductor. Such a range provides a convenient tolerance for unlanded vias while still enabling a small pitch between neighboring conductors (which is beneficial for the packing density).

The invention further relates to a method of manufacturing a semiconductor device, which comprises steps of:
providing a substrate, the substrate comprising a body, the body having a surface, the substrate being provided with an insulating layer on the surface of the body;
forming a conductor with insulating sidewall spacers in the insulating layer, the conductor having a current-flow direction during operation, the conductor having a first width, the insulating sidewall spacers each having a second width being smaller than the first width of the conductor, the first width and the second width being measured in a direction perpendicular to the current-flow direction of the conductor and parallel to said surface, the conductor having a first top surface extending parallel to said surface, the insulating sidewall spacers having a second top surface, the first top surface coinciding with the second top surface, and
forming airgaps in the insulating layer adjacent to the insulating sidewall spacers, the airgaps extending from the surface of the body to said first and second top surface.

The method of manufacturing according to the invention provides a convenient way of forming a semiconductor device that enables a lower resistance of the conductor while still providing a tolerance for unlanded vias.

Preferably, in the step of providing the substrate, the insulating layer has been provided with an opening having sidewalls, the opening having a third width, the third width being measured in the direction parallel to said surface, and in that the conductor is provided in the opening. This feature enables a number of advantageous main variants of the method.

A first main variant of the method according to the invention is characterized in that, the step of forming the conductor with insulating sidewall spacers, comprises:
a first sub-step in which the insulating sidewall spacers are formed on the sidewalls of the opening, the second width of the insulating sidewall spacers being smaller than one third of the third width of the opening; and
a second sub-step in which the conductor is formed in the opening between the insulating sidewall spacers. The advantage of this main variant of the method is that the insulating sidewall spacers can be formed in a well-controlled way, for example by means of depositing an insulating layer inside the opening and then performing an etch-back step, which forms the insulating sidewall spacers.

An advantageous improvement of the first main variant of the method according to the invention is characterized in that, in the step of providing the substrate, at least parts of the insulating layer, located adjacent to the opening, have been provided as sacrificial regions, and in that the airgaps are formed by removing the sacrificial regions after that the insulating sidewall spacers and the conductor have been formed. The advantage of this improved embodiment is that the airgaps are formed in a well-controlled way in two steps. In a first step the airgaps to be formed are defined by the sacrificial regions, whereafter in a second step the airgaps are physically formed by removing the sacrificial regions.

In a further improved embodiment of the first variant of the method according to the invention the sacrificial regions have been formed by local damaging of material of the insulating layer. This step enables selective removal of said material for forming the airgaps.

Preferably, in the last mentioned embodiment, the step of locally damaging of material of the insulating layer takes place during formation of the opening by means of etching. This is an advantage embodiment because it saves process steps and thus costs.

Alternatively, the sacrificial regions can be provided with a different material as the insulating layer, which also enables selective removal of the sacrificial regions.

In a further improvement on all mentioned embodiments falling under the scope of the first main variant the insulating layer is fully provided as sacrificial region. This is advantageous because it results in a full airgap semiconductor device instead of a partial airgap semiconductor device, and complete airgaps (airgaps which extend from the sidewall spacer of one conductor to the sidewall spacer of a neighboring conductor in the same insulating layer) result in a lower parasitic capacitance of the conductor, which results in a better performance of the semiconductor device.

A second main variant of the method according to the invention is characterized in that, in the step of providing the substrate, parts of the insulating layer, located at a predefined distance from the opening, have been provided as sacrificial regions which define insulating regions between the conductor and the sacrificial regions, the predefined distance being smaller than the first width of the conductor, wherein the insulating sidewall spacers are defined by the insulating regions, and in that the airgaps are formed by removing the sacrificial regions which further forms the insulating sidewall spacers.

Preferably, in the last mentioned main variant the sacrificial regions are formed by local damaging of material of the insulating layer by means of ion bombardment. This step enables selective removal of said material for forming the airgaps.

Alternatively, the sacrificial regions can be provided with a different material as the insulating layer, which also enables selective removal of the sacrificial regions.

Preferably in all embodiments of the semiconductor device is provided with a further insulating layer, the further insulating layer being provided with a further opening, the further opening being filled with a further conductor, wherein at least one part of the further conductor lands on the first top surface of the conductor. This embodiment is advantageous because it provides a semiconductor device in which an unlanded via does not necessarily end up in one of the airgaps next to the spacers. Such a situation would be detrimental for the reliability of the semiconductor device.

Preferably, at least a top part of the further conductor is provided with further spacers. Such a measure ensures a tolerance for unlanded vias for higher interconnect layers comprising other conductors, which need to be connected to the further conductor.

Preferably, the insulating sidewall spacers are provided with a width that lies between 5% and 40% of the width of the conductor. Such a range provides a convenient tolerance for unlanded vias while still enabling a small pitch between neighboring conductors (which is beneficial for the packing density).

An important improved semiconductor device is obtained if the method according to the invention is characterized in that, before the step of providing the conductor, a diffusion barrier layer is provided in the opening for encapsulating the conductor. This measure enables the usage of materials like copper for the conductor, which tends to diffuse through the semiconductor device and cause reliability problem when penetrating the substrate having active devices therein.

Additionally, a diffusion barrier layer can be provided on top of the conductor for further encapsulation of the conductor, wherein a top surface of the diffusion barrier layer is considered as the top surface of the conductor.

### BRIEF DESCRIPTION OF THE DRAWINGS

Any of the additional features can be combined together and combined with any of the aspects. Other advantages will be apparent to those skilled in the art. Numerous variations and modifications can be made without departing from the scope of the claims of the present invention. Therefore, it should be clearly understood that the present description is illustrative only and is not intended to limit the scope of the present invention.

How the present invention may be put into effect will now be described by way of example with reference to the appended drawings, in which:

FIGS. 1a to 1f illustrate a method of manufacturing a semiconductor device as known from the prior art;

FIGS. 2a and 2b illustrate the unlanded-via problem being present in the known method;

FIG. 3a illustrates a known semiconductor device, which provides an inferior solution to the unlanded-via problem;

FIG. 3b illustrates the semiconductor device according to the invention, which provides a better solution to the unlanded-via problem;

FIGS. 4a to 4h illustrate a first embodiment of the method of manufacturing a semiconductor device according to the invention; and

FIGS. 5a to 5g illustrate a second embodiment of the method of manufacturing a semiconductor device according to the invention.

### DETAILED DESCRIPTION OF EMBODIMENTS

Introducing airgaps as a replacement of low-k dielectric in the back-end-of-line processing (BEOL) is seen as a promising solution for reaching very low parasitic capacitance values of on-chip interconnect. Different airgap configurations have been published. Sometimes airgaps are created fully extending between two interconnect lines (called complete airgaps), while in other cases the airgap is created only in confined areas next to interconnect lines (called partial airgaps). The invention according to the invention is applicable in both configurations.

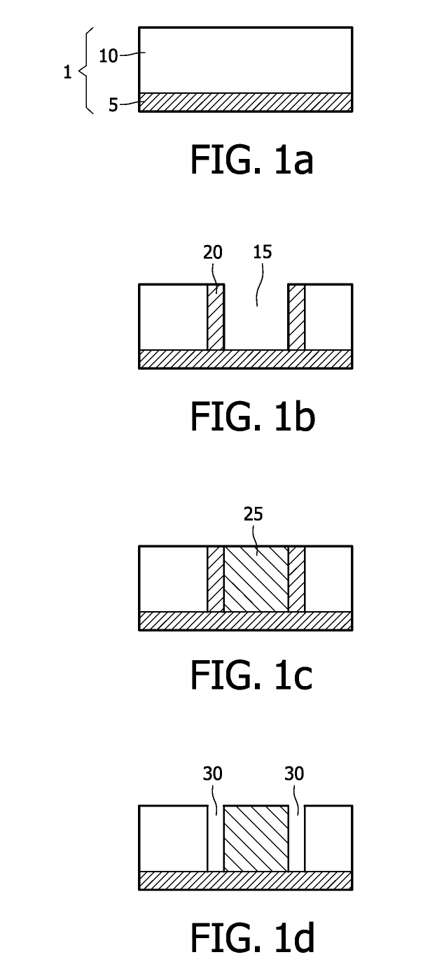

FIGS. 1a to 1f illustrate a method of manufacturing a semiconductor device as known from the prior art. FIG. 1a illustrates an intermediate stage of the known method, wherein a substrate 1 (not shown) is provided, the substrate 1 comprising a body (not shown) having a surface 3. An etch stop layer 5 has been provided on the surface 3 of the body. An insulating layer 10 has been provided on the etch stop layer 5.

In embodiments of the present invention, the body of the substrate 1 may include any underlying material or materials that may be used, or upon which a device, a circuit or an epitaxial layer may be formed. In other alternative embodiments, this body may include a semiconductor substrate such as e.g. a doped silicon, a gallium arsenide (GaAs), a gallium arsenide phosphide (GaAsP), an indium phosphide (InP), a germanium (Ge), or a silicon germanium (SiGe) substrate. The body may include for example, an insulating layer such as a SiO2 or a Si3N4 layer in addition to a semiconductor substrate portion. Thus, the term body also includes glass, plastic, ceramic, silicon-on-glass, and silicon-on sapphire substrates. The term body is thus used to define generally the elements for layers that underlie a layer or portions of interest. Also, the body may be any other base on which a layer is formed, for example a glass or metal layer. Hence, this body can be any material, which is suitable for inlaying a damascene structure, including an oxide layer such as silicon dioxide or TEOS for example. It can be formed on top of other underlying layers, including substrates and semiconductor or conductive layers.

In embodiments of the present invention, the etch stop layer may comprise at least one material selected from a group comprising silicon nitride (SiN), silicon oxynitride (SiON), aluminum oxide (Al₂O₃), aluminum nitride (AlN), silicon carbide (SiC), silicon carbonitride (SiCN) and Aluminum silicide. The etch stop layer 5 is optional. The necessity depends on the presence of underlying layers having the right pattern or etch-rate (preferably a lower etch-rate). The function of the etch stop layer 5 is to enhance the forming of openings and trenches later in the manufacturing process.

In embodiments of the present invention, the insulating layer may comprise materials like: silicon oxide (SiO2), Black Diamond™, Orion™, Aurora™, Silk™, p-Silk™ and other low-k dielectric constant materials being investigated or in used in IC manufacturing processes.

FIG. 1b illustrates another stage of the known method, wherein an opening 15 is etched in the insulating layer 10. During the etching of the opening 15 (for example by means of plasma etching), the sidewalls of the opening 15 are damaged such that they are converted into sacrificial regions 20, which can be selectively removed in a later stage. The opening 15 may have any shape and defines a conductor 25 to be formed later in the manufacturing process. It may have straight sidewalls or angled sidewalls.

FIG. 1c illustrates another stage of the known method, wherein a conductor 25 is provided in the opening 15. This may be done by first depositing a conductive layer 25 over the insulating layer 10 and in the opening 15, followed by a polishing step (e.g. CMP) for removing the redundant material outside the opening. In embodiments of the invention the conductor 25 may comprise materials like: copper, tungsten. aluminum, aluminum alloy, polysilicon, metal, and metal allow.

FIG. 1d illustrates another stage of the known method, wherein the airgaps 30 are formed by selective removal of the sacrificial regions 25. This removal can be done by means of a wet-etching step. In embodiments of the invention the term “airgap” refers to an air dielectric, a gas gap, a gas dielectric, or any gas-phase dielectric.

FIG. 1e illustrates another stage of the known method, wherein a further etch stop layer 35 is provided over the insulating layer 10, the airgaps 30 and the conductor 25, which closes off the airgaps. This may be done using non-conformal chemical-vapor-deposition techniques (CVD).

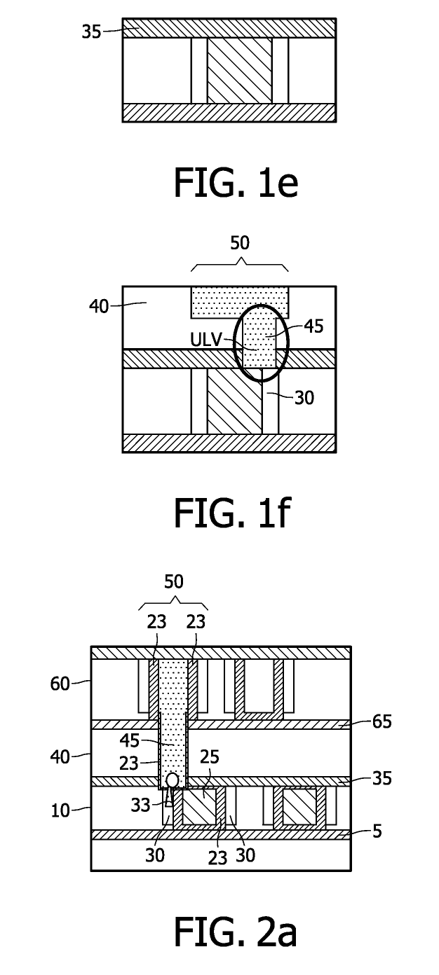

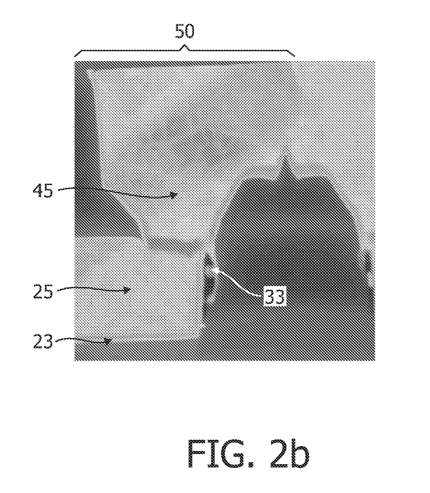

FIG. 1f illustrates a stage of the known method, wherein a further insulating layer 40 is provided on top of the further etch stop layer 35. The further insulating layer 40 has a further opening that extends to the insulating layer 10. The further opening comprises a further conductor structure 50, which lands with a bottom part 45 (a via) on the conductor 30. There is a misalignment between the via 45 and the conductor 25 which causes the via 45 to be partially located above the airgap 30. In prior art, this is called an unlanded via. The unlanded via ULV may create some problems, which will be explained the description of FIGS. 2a and 2b. In FIGS. 1f, 3b, and 4h a dual damascene structure 45,50 is formed above the conductor 30. However, in embodiments of the present invention, a single damascene structure or other structure types could also be formed without departing from the scope of the invention.

FIGS. 2a and 2b illustrate the unlanded-via problem being present in the known method. In this figure, a semiconductor device is presented having a conductor 25 in a first insulating layer 10. In this particular example, the conductor 25 has been provided with a diffusion barrier layer 23. The necessity of the barrier layer 23 depends on the material used for the conductor 25. In particular, materials such as copper need such a diffusion barrier layer 23 in order to prevent diffusion of this material into the substrate, which is detrimental for the operation of the semiconductor device.

Further conductors 50 are provided in a further insulating layer 60 above the first insulating layer 10. The further conductors 50 are connected to the conductors 25 by a via 45. The via is located in a second insulating layer 40 separated from the further insulating layer 60 in which the further conductor 50 is located. The example illustrated in FIG. 2a is a dual-damascene device. However, the problem illustrated in this Figure may also occur in a single-damascene device. In this example, there is a misalignment between the via 45 and the conductor 25, which makes the via 45 a so-called “unlanded via”. An unlanded via may cause reliability issues as material 33 of the via (e.g. copper) in the via which may end up in the airgap 30 after thermal cycling. Thermal cycling is a test which is usually done for reliability assessment. The test consists of steps of heating the structure at 400° C. for about 1 hour while following the via resistance after 1, 2, and 3 cycles. Usually, when an increase of via resistance is seen there is a reliability issue.

FIG. 2b shows a TEM image of a semiconductor device having the unlanded-via problem. The material 33, which has entered the airgap, is clearly visible. In FIG. 2a the insulating layers 10, 40, 60 are separated by etch-stop layers 5, 35, 65, which are preferably used.

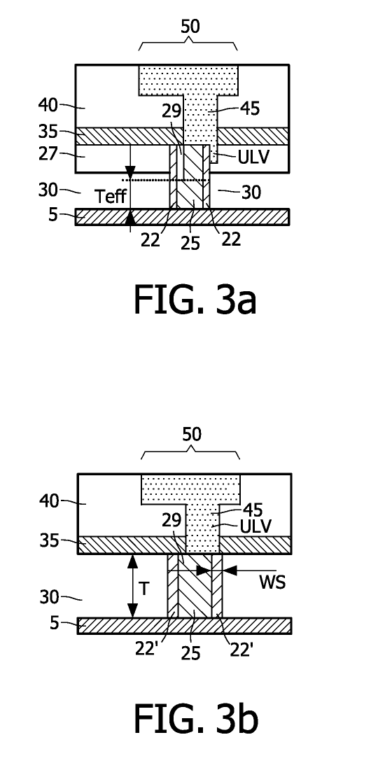

FIG. 3a illustrates a known semiconductor device, which provides an inferior solution to the unlanded-via problem. This semiconductor device is having an unlanded via ULV and is known from US2001/0016412A1. The semiconductor device differs from the semiconductor device FIG. 1f in that a capping layer is provided above the airgap 30 which serves during the formation of an opening for the via 45 as some sort of etch-stop layer. A further difference lies in the fact that above the conductor 25 a further non-conducting capping layer 29 is present. This non-conducting capping layer 29 serves during the manufacturing of an opening for the via 45 as some sort of a sacrificial layer and is therefore made of a material having a higher etch rate than the capping layer 27 and sidewall spacers 22. The sidewall spacers 22 of the conductor 25 close off the airgap 30 during this formation. Thus, during the formation of the opening for the via 45 these measures prevent that the airgap 30 is reached earlier than the conductor 25. This can be done by an etch-step having an end-point detection on reaching of the conductor 25. An unlanded via ULV in a later stage cannot border on the airgap 30, which solves the reliability problem associated with material of the unlanded via ULV entering the airgap 30 after thermal cycling of the semiconductor device.

FIG. 3b illustrates the semiconductor device according to the invention, which provides a better solution to the unlanded-via problem. The semiconductor device from FIG. 3b differs from the one in FIG. 3a in that no capping layer 27 is present above the airgap 30 that extends to below the upper surface of the conductor 25. Furthermore, there is no non-conducting capping layer 29 present on the conductor 25. Instead, the semiconductor device has been provided with insulating sidewalls spacers 22′. The unlanded via ULV lands on a top surface of the insulating sidewall spacers 22′. Preferably, the insulating sidewall spacers 22′ have a width WS between 5% and 40% of the width of the conductor 25.

The invention is based upon the insight that the problem resulting from a unlanded via ULV can be solved with the spacers 22′ themselves. This can be done by making the spacers 22′ extend to the top of the conductor 25 while at the same time making the airgaps 30 extend to the top surface of the spacer 22′ and the conductor 25. This combination of features excludes the possibility of a capping layer that extends to below the top surface of the conductor 25. Above that, such capping layer is not needed anymore. The combination of all mentioned features further makes the conductor 25 benefit fully from the vertical space T available in the insulating layer, which on its turn allows for a larger cross-sectional area of the conductor 25 at a specific interconnect width. A larger cross-sectional area implies a lower interconnect resistance and thus the object of the invention is achieved. In FIG. 3a the effective thickness Teff of the conductor 25 is significantly reduced by the presence of the capping layer 29.

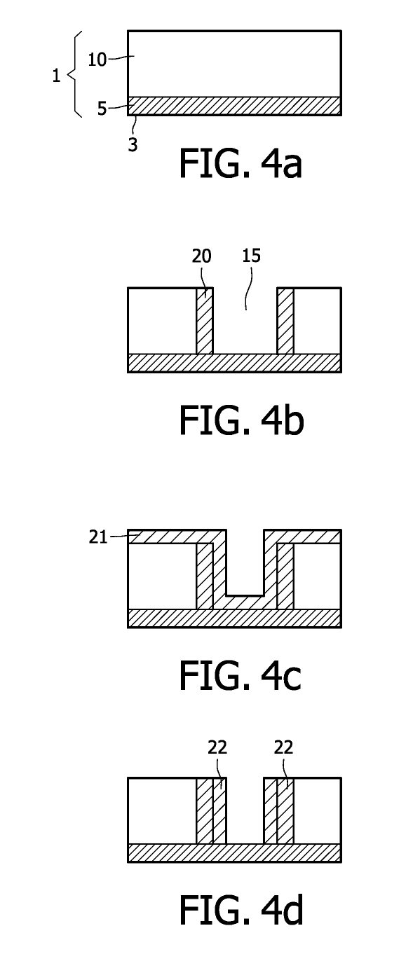

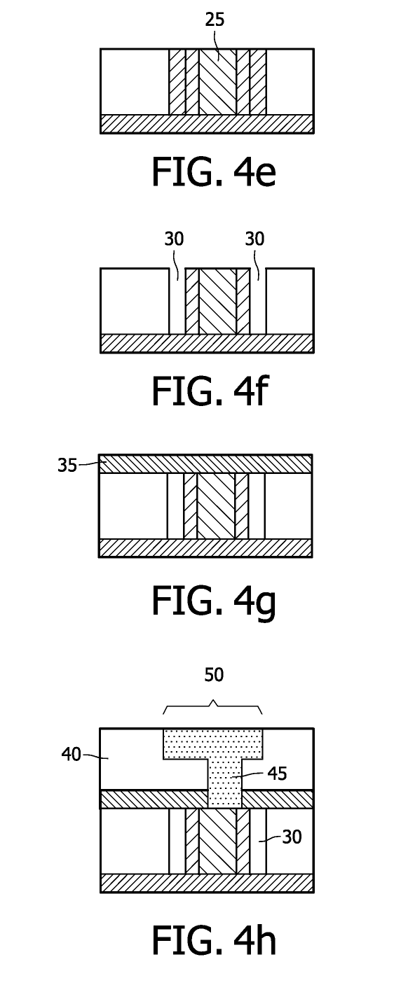

FIGS. 4a to 4h illustrate a first embodiment of the method of manufacturing a semiconductor device according to the invention. This embodiment will be mainly discussed as far as it differs from the known method as illustrated in FIGS. 1a to 1f.

The stage of the method according to the invention as illustrated in FIG. 4a is similar to the stage of the known method in FIG. 1a.

The stage of the method according to the invention as illustrated in FIG. 4b is similar to the stage of the known method in FIG. 1b.

Referring to FIG. 4c, in this stage an insulating spacer layer 21 is provided on the insulating layer 10 and on all walls of the opening 15. The thickness of this insulating spacer layer 21 determines the width of the insulating sidewall spacers 22 which will be formed later. The insulating spacer layer 21 can be provided using conventional deposition techniques like CVD, ALD, spin-on coating etc. Referring to FIG. 4d, in this stage the insulating sidewall spacers 22 are formed by an anisotropic etch-back step. The spacer material can be any oxide material (e.g. SiO2 or FSG) or SiOCH low-k materials. But also nitrides (like SiN) can be used, which may also be used in the frond-end for spacers of the gate. An important characteristic of the material for the insulating sidewall spacers 21 is that the spacers remain unchanged during the step of forming airgaps afterwards.

All other steps as illustrated in FIG. 4e to FIG. 4h are similar to the ones illustrated in FIG. 1c to FIG. 1f.

In a variation on the first embodiment of the method according to the invention, the provision of the insulating spacer layer 21 (FIG. 4c) can be used to make more or less plasma damage on the low k, leading to different air gap dimensions (FIG. 4g).

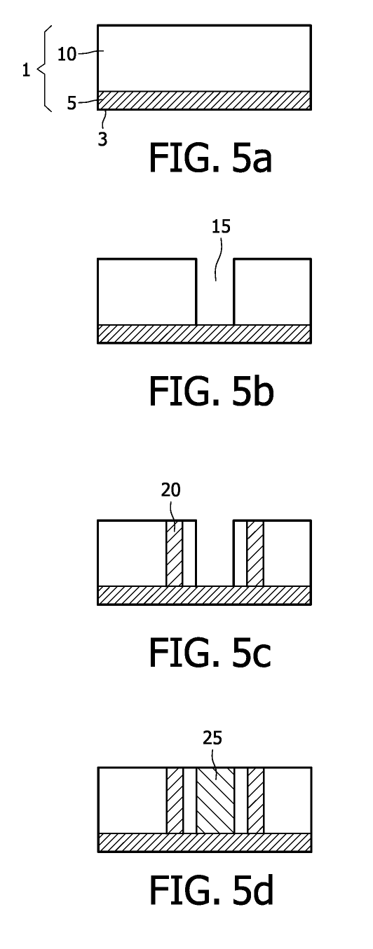

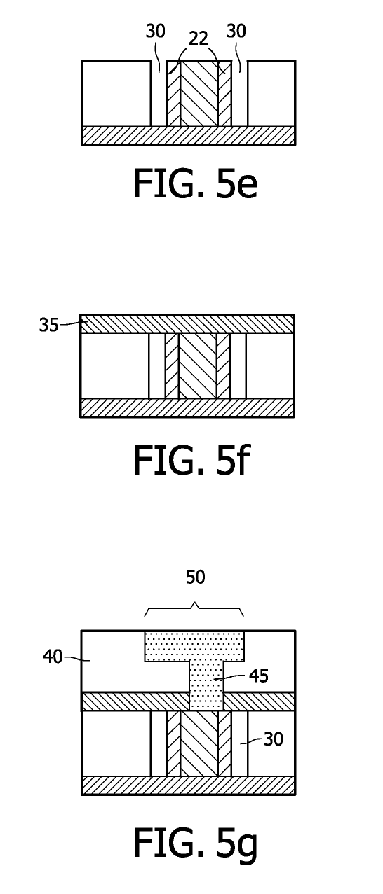

FIGS. 5a to 5g illustrate a second embodiment of the method of manufacturing a semiconductor device according to the invention. This embodiment will be mainly discussed as far as it differs from the first embodiment of the method as illustrated in FIGS. 4a to 4h. The main difference lies in the fact that the insulating sidewall spacers 22 will now be indirectly formed out of the original insulating layer 10.

The stage of the method as illustrated in FIG. 5a is similar to 4a.

The stage of the method as illustrated in FIG. 5b slightly differs from the stage of the method as illustrated in FIG. 4b, in that the width of the opening 15 is now dimensioned to have a width comparable to the width of the conductor 25 to be formed later. In FIG. 4b this width should be the width of the conductor 25 plus two times the width of the insulating sidewall spacers 22.

In the stage of the method as illustrated in FIG. 5c the sacrificial regions 20 are formed at located at a predefined distance from the opening 15. These sacrificial regions 20 define insulating regions between the conductor 25 and the sacrificial regions 20, wherein the insulating sidewall spacers 22 are defined by the insulating regions.

The stages of the method as illustrated in FIG. 5d to FIG. 5g are similar to 4e to FIG. 4h. It is important to note that the spacers 22 are actually formed in the same step as the formation of the airgaps 30, thus in FIG. 5e.

Various variations of the method are possible. The first and the second embodiment of the method can even be combined without any problems.

Although the given examples in FIGS. 1f, 4h and 5g present a dual-damascene interconnect layer 40, 45, 50, the invention can be easily applied in single-damascene processes as well.

Also, the invention is applicable in both complete airgap configurations, as well as partial airgap configurations. One way of creating full airgap configurations is to implement the insulating layer 10 as a fully as a sacrificial layer.

As an alternative to the methods illustrated in FIGS. 4a to 4h and FIGS. 5a to 5g it is also possible to provide the sacrificial regions 20 (or the complete insulating layer, when complete airgaps are desired) as a thermal degradable material. The formation of the airgaps 30 may then be done by thermal degradation of the thermodegradable material.

The invention thus provides a semiconductor device comprising:
a substrate, the substrate comprising a body, the body having a surface, the substrate being provided with an insulating layer on the surface of the body;
a conductor with insulating sidewall spacers located in the insulating layer, the conductor having a current-flow direction during operation, the conductor having a first width, the insulating sidewall spacers each having a second width being smaller than the first width of the conductor, the first width and the second width being measured in a direction perpendicular to the current-flow direction of the conductor and parallel to said surface, the conductor having a first top surface extending parallel to said surface, the insulating sidewall spacers having a second top surface, and
airgaps located in the insulating layer adjacent to the insulating sidewall spacers, wherein the first top surface coincides with the second top surface, and in that the airgaps extend from the surface of the body to said first and second top surface.

An inventive thought behind the invention is not to make the airgaps 30 close to the conductor 25. Instead spacers are formed next to the conductor for creating an unlanded-via tolerance (by letting the unlanded via land on the spacers) while effectively increasing the cross-sectional area of the conductor and thus reducing the resistance thereof.

The invention also provides methods of manufacturing such a semiconductor device.

The present invention has been described with respect to particular embodiments and with reference to certain drawings but the invention is not limited thereto but only by the claims. Any reference signs in the claims shall not be construed as limiting the scope. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

1. A semiconductor device comprising:
a substrate, the substrate comprising a body, the body having a surface, the substrate being provided with an insulating layer on the surface of the body;
a conductor with insulating sidewall spacers located in the insulating layer, the conductor having a current-flow direction during operation, the conductor having a first width, the insulating sidewall spacers each having a second width being smaller than the first width of the conductor, the first width and the second width being measured in a direction perpendicular to the current-flow direction of the conductor and parallel to said surface, the conductor having a first top surface extending parallel to said surface, the insulating sidewall spacers having a second top surface, and
airgaps located in the insulating layer adjacent to the insulating sidewall spacers,
characterized in that the first top surface coincides with the second top surface, and in that the airgaps extend from the surface of the body to said first and second top surface.

2. A semiconductor device as claimed in claim 1, characterized in that the substrate further comprises a further insulating layer being provided on top of the insulating layer, the further insulating layer being provided with a further opening, the further opening being filled with a further conductor, wherein at least one part of the further conductor lands on the first top surface of the conductors.

3. A semiconductor device according to claim 1, characterized in that the width of the insulating sidewall spacers lies between 5% and 40% of the width of the conductor.

4. A method of manufacturing a semiconductor device comprising steps of:
providing a substrate, the substrate comprising a body, the body having a surface, the substrate being provided with an insulating layer on the surface of the body;
forming a conductor with insulating sidewall spacers in the insulating layer, the conductor having a current-flow direction during operation, the conductor having a first width, the insulating sidewall spacers each having a second width being smaller than the first width of the conductor, the first width and the second width being measured in a direction perpendicular to the current-flow direction of the conductor and parallel to said surface, the conductor having a first top surface extending parallel to said surface, the insulating sidewall spacers having a second top surface, the first top surface coinciding with the second top surface, and
forming airgaps in the insulating layer adjacent to the insulating sidewall spacers, the airgaps extending from the surface of the body to said first and second top surface.

5. A method as claimed in claim 4, characterized in that, in the step of providing the substrate, the insulating layer has been provided with an opening having sidewalls, the opening having a third width, the third width being measured in the direction parallel to said surface, and in that the conductor is provided in the openings.

6. A method as claimed in claim 5, characterized in that the step of forming the conductor with insulating sidewall spacers, comprises:
a first sub-step in which the insulating sidewall spacers are formed on the sidewalls of the opening, the second width of the insulating sidewall spacers being smaller than one third of the third width of the opening; and
a second sub-step in which the conductor is formed in the opening between the insulating sidewall spacers.

7. A method as claimed in claim 6, characterized in that, in the step of providing the substrate, at least parts of the insulating layer, located adjacent to the opening, have been provided as sacrificial regions, and in that the airgaps are formed by removing the sacrificial regions after that the insulating sidewall spacers and the conductor have been formed.

8. A method as claimed in claim 7, characterized in that the sacrificial regions have been formed by local damaging of material of the insulating layer.

9. A method as claimed in claim 8, characterized in that the step of locally damaging of material of the insulating layer takes place during formation of the opening by means of etching.

10. A method as claimed in claim 5, characterized in that, in the step of providing the substrate, parts of the insulating layer, located at a predefined distance from the opening, have been provided as sacrificial regions which define insulating regions between the conductor and the sacrificial regions, the predefined distance being smaller than the first width of the conductor, wherein the insulating sidewall spacers are defined by the insulating regions, and in that the airgaps are formed by removing the sacrificial regions which further forms the insulating sidewall spacers.

11. A method as claimed in claim 10, characterized in that the sacrificial regions are formed by local damaging of material of the insulating layer by means of ion bombardment.

12. A method as claimed in claim 4, characterized in that the insulating layer is fully provided as sacrificial region.

13. A method as claimed in claim 4, characterized in that the semiconductor device is provided with a further insulating layer, the further insulating layer being provided with a further opening, the further opening being filled with a further conductor, wherein at least one part of the further conductor lands on the first top surface of the conductor.

14. A method as claimed in claim 13, characterized in that at least a top part of the further conductor is provided with further spacers.

15. A method according to claim 4, characterized in that the insulating sidewall spacers are provided with a width that lies between 5% and 40% of the width of the conductor.
